(19) United States
(12) Patent Application Publication
(10) Pub. No.: US 2009/0322332 A1
(43) Pub. Date: Dec. 31, 2009

(54) NMR probe superconductive transmit/receive switches

(75) Inventor: Jason W. Cosman, Mountain View, CA (US)

Correspondence Address: Varian Inc.;Legal Department, 3120 Hansen Way D-102, Palo Alto, CA, 94304, US

(73) Assignee: Varian, Inc.

(21) Appl. No.: 11/729,062

(22) Filed: Mar. 28, 2007

(51) Int. Cl. G01R 33/44

(52) U.S. Cl. 324/318

(57) ABSTRACT

A NMR (nuclear magnetic resonance) transmit/receive switch according to some embodiments of a nuclear magnetic resonance apparatus includes receive-path and/or transmit-path superconductors, which are selectively quenched to switch the connection of an NMR radio-frequency coil between transmit and receive circuits. In the transmit state, the transmit-path superconductor is in a superconducting state while the receive-path superconductor is quenched, to isolate a receive-path amplifier from the relatively higher powers of the NMR pulses applied to the sample by the transmit circuit. In the receive state, the receive-path superconductor is in a superconducting state while the transmit-path superconductor is quenched. A DC power source is used to supply supercritical current to the superconductors to quench the superconductors.

### FIELD OF THE INVENTION

The invention in general relates to nuclear magnetic resonance (NMR) spectroscopy, and in particular to transmit/receive switch systems and methods for NMR probes.

### BACKGROUND OF THE INVENTION

Nuclear magnetic resonance (NMR) spectrometers typically include a superconducting magnet for generating a static magnetic field B₀, and an NMR probe including one or more special-purpose radio-frequency (RF) coils for generating a time-varying magnetic field B₁ perpendicular to the field B₀, and for detecting the response of a sample to the applied magnetic fields. Each RF coil and associated circuitry can resonate at the Larmor frequency of a nucleus of interest present in the sample. The RF coils are typically provided as part of an NMR probe, and are used to analyze samples situated in sample tubes or flow cells.

An NMR coil may be used for both applying RF pulses to a sample and for detecting the sample's response to the applied RF pulses. In such a system, a transmit/receive switch may be employed to connect the coil to transmit circuitry during the transmission phase, and to receive circuitry during the detection phase. The transmit/receive switch protects the receive circuitry, particularly any receive circuit amplifiers, from the relatively high powers of the RF pulses applied to the coil during a transmit phase. Some conventional transmit/receive switches employ diodes formed on a silicon integrated circuit to perform the switching function. Such silicon diodes may not perform optimally as their temperature is reduced.

### SUMMARY OF THE INVENTION

According to one aspect, the present invention provides a nuclear magnetic resonance (NMR) apparatus comprising a nuclear magnetic resonance radio-frequency coil, and a superconducting transmit/receive switch electrically connecting the radio-frequency coil alternatively to a transmit circuit and to a receive circuit. The transmit/receive switch includes a receive-path superconductor situated in an electrical path between the receive circuit and the radio-frequency coil. In a receive state of the switch, the receive-path superconductor is in a superconducting state, to connect the receive circuit to the radio-frequency coil. In a transmit state of the switch, the receive-path superconductor is in a normal state, to isolate the receive circuit from the radio-frequency coil.

According to another aspect, a nuclear magnetic resonance method comprises applying a set of pulses to a nuclear magnetic resonance radio-frequency coil while quenching a receive-path superconductor situated in an electrical path between the radio-frequency coil and a receive-path amplifier, and employing the receive-path amplifier to amplify a nuclear magnetic resonance response to the set of pulses while maintaining the receive-path superconductor in a superconducting state.

### BRIEF DESCRIPTION OF THE DRAWINGS

The foregoing aspects and advantages of the present invention will become better understood upon reading the following detailed description and upon reference to the drawings where:

FIG. 1 is a schematic diagram of an exemplary NMR spectrometer according to some embodiments of the present invention.

FIG. 2 shows a part of an NMR probe including a superconducting transmit/receive switch according to some embodiments of the present invention.

FIG. 3 illustrates a connection between a superconducting lead and adjacent normal metal conductors according to some embodiments of the present invention.

FIG. 4 shows an exemplary superconducting transmit/receive switch according to some embodiments of the present invention.

FIGS. 5A-5B show exemplary superconducting transmit/receive switch configurations according to some embodiments of the present invention.

### DETAILED DESCRIPTION OF THE INVENTION

In the following description, a set of elements includes one or more elements. A plurality of elements includes two or more elements. Any reference to an element is understood to encompass one or more elements. Each recited element or structure can be formed by or be part of a monolithic structure, or be formed from multiple distinct structures. The statement that a coil is used to perform a nuclear magnetic measurement on a sample is understood to mean that the coil is used as transmitter, receiver, or both. Any recited electrical or mechanical connections can be direct connections or indirect connections through intermediary circuit elements or structures. Unless otherwise qualified, the term superconductor encompasses superconductors in a superconducting state as well as superconductors in a non-superconducting (normal) state.

The following description illustrates embodiments of the invention by way of example and not necessarily by way of limitation.

FIG. 1 is a schematic diagram illustrating an exemplary nuclear magnetic resonance (NMR) spectrometer 12 according to some embodiments of the present invention. Spectrometer 12 comprises a magnet 16, an NMR probe 20 inserted in a cylindrical bore of magnet 16, and a control/acquisition console 18 electrically connected to magnet 16 and probe 20. Probe 20 may be a cryogenically-cooled (cold) probe. Probe 20 includes one or more radio-frequency (RF) coils 24 and associated electrical circuit components. For simplicity, the following discussion will focus on a single coil 24, although it is understood that a system may include other similar coils. A sample container 22 is positioned within probe 20, for holding an NMR sample of interest within coil 24 while measurements are performed on the sample. Sample container 22 may be a sample tube or a flow cell. A number of electrical circuit components such as capacitors, inductors, amplifiers, a transmit/receive switch and other components are situated in a circuit region 26 of probe 20, and are connected to coil 24. Coil 24 and the various components connected to coil 24 form one or more NMR measurement circuits.

To perform a measurement, a sample is inserted into coil 24. Magnet 16 applies a static magnetic field B₀ to the sample held within sample container 22. Control/acquisition console 18 comprises a transmit circuit configured to apply desired radio-frequency pulses to coil 24, and a receive circuit configured to acquire data indicative of the nuclear magnetic resonance properties of the sample within coil 24. Coil 24 is used to apply radio-frequency magnetic fields B₁ to the sample, and/or to measure the response of the sample to the applied magnetic fields. The RF magnetic fields are perpendicular to the static magnetic field. The same coil may be used for both applying an RF magnetic field and for measuring the sample response to the applied magnetic field.

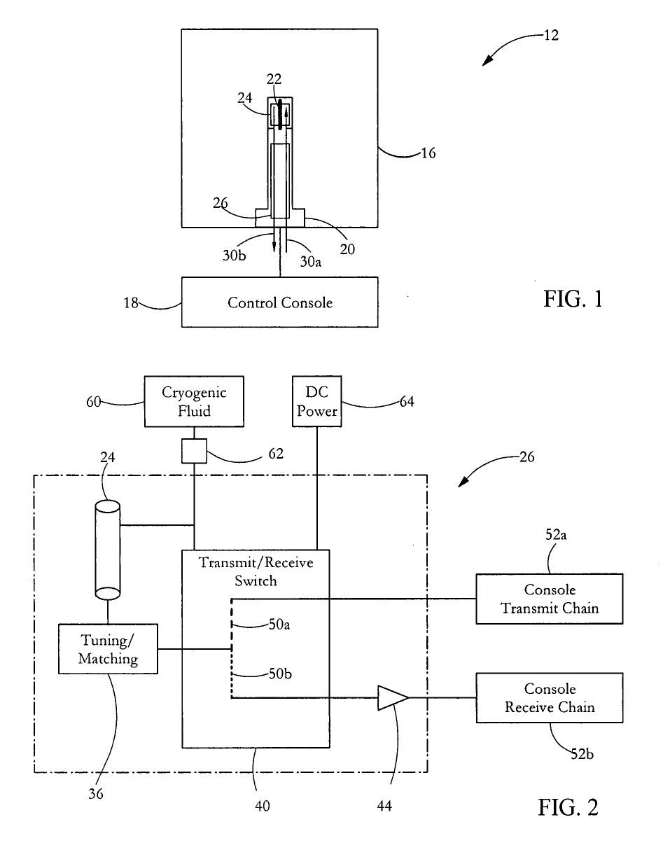

FIG. 2 shows part of an NMR spectrometer including a superconducting transmit/receive switch 40 according to some embodiments of the present invention. Transmit/receive switch 40 may be positioned within the circuit region 26 of the NMR probe, underneath coil 24. Transmit/receive switch 40 is connected to RF coil 24 through a tuning/matching circuit 36. Tuning/matching circuit 36 may include variable capacitors and other components for tuning the resonant frequency of the NMR measurement circuit including RF coil 24, and for matching the impedance of the NMR measurement circuit to its environment.

Transmit/receive switch 40 connects RF coil 24 alternatively to a console transmit chain 52a and a console receive chain 52b. In a transmit state, switch 40 connects transmit chain 52a to coil 24, while in a receive state, switch 40 connects receive chain 52b to coil 24. Transmit chain 52a includes circuitry configured to apply NMR pulses to coil 24, while receive chain 52b includes circuitry configured to detect the response of the NMR sample within coil 24 to the applied pulses. Generally, the applied pulses have much higher powers than the detected response signals. In exemplary embodiments, the applied pulses have power levels on the order of −20 to +60 dBm, for example about 30-50 dBm, while the detected response signals have power levels many (e.g. 10) orders of magnitude lower, often on the order of −120 to −160 dBm, for example about −160 dBm. A receive amplifier 44 connects transmit/receive switch 40 to receive chain 52b. Receive amplifier 44 amplifies detected response signals received from coil 24, and sends the amplified signals to receive chain 52b.

Transmit/receive switch 40 includes a transmit-path superconducting lead 50a forming part of an electrical path between coil 24 and transmit chain 52, and a receive-path superconducting lead 50b forming part of an electrical path between coil 24 and receive chain 52b. In particular, leads 50a-b may be identical parts of a monolithically formed superconductor lead electrically connected at its ends to transmit chain 52a and receive chain 52b, and electrically connected at an internal point (e.g. at midpoint) to coil 24. The rest of the conductors shown in FIG. 2 may be formed by normal (resistive) metal and/or superconductor leads.

A cryogenic fluid source 60 is fluidically connected to transmit/receive switch 40, coil 24 and other conductive components of probe 20 through one or more valves 62. Cryogenic fluid source 60 provides a cryogenic fluid such as cold gaseous helium to maintain superconducting leads 50a-b below their critical temperature (or temperatures, if different materials are used for the two leads). Under the critical temperature, leads 50a-b are in a superconducting state if the currents through leads are below a critical current value. A DC power source 64 is electrically connected to transmit/receive switch 40, and in particular to leads 50a-b. DC power source 64 is used to selectively quench each lead 50a-b by running a super-critical current alternatively through each lead. Quenching a lead transitions the lead from a superconducting to a non-superconducting (normal) state.

The material(s) and/or dimensions used for leads 50a-b may be chosen so that leads 50a-b are quenched by available current levels. In some embodiments, a width of each lead 50a-b may be on the order of 0.0001″ to 0.1″, for example between 0.001″ and 0.01″, and a height of each lead 50a-b may be between 0.01 μm (micron) and 100 μm, for example between 0.1 μm and 10 μm. The material(s) used for leads 50a-b may be chosen according to their critical currents, tolerance to magnetic fields, and suitability for patterning on a desired substrate. In some embodiments, leads 50a-b may be formed from a high-temperature superconductor having a critical temperature above the boiling point of nitrogen, for example from Yttrium Barium Copper Oxide (YBCO), a ceramic superconductor. In some embodiments, the substrate on which leads 50a-b are formed may include insulators such as sapphire, MgO, or quartz.

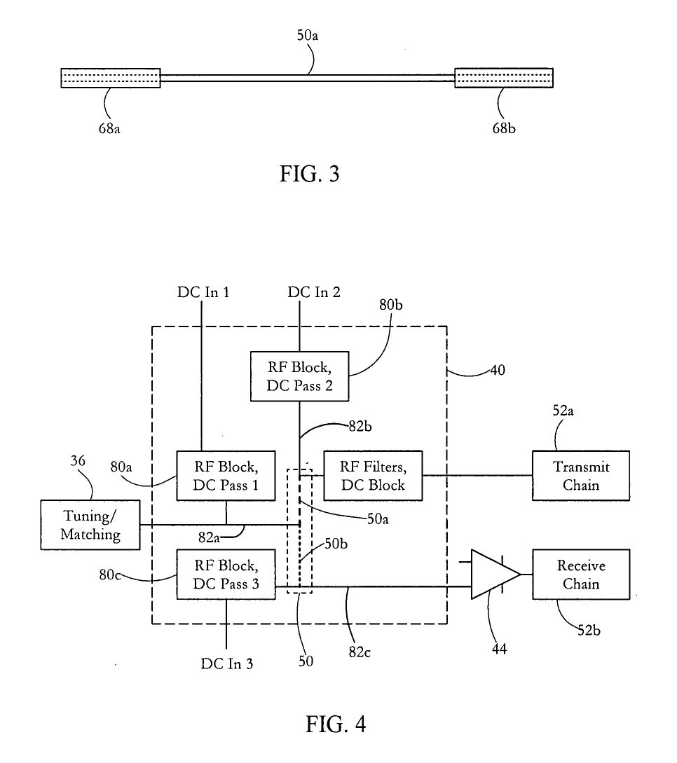

In some embodiments, leads 50a-b are connected to adjacent resistive metal conductors by patterning resistive metal on the ends of leads 50a-b. Suitable resistive metals for metalizing leads 50a-b and for other conductors may include gold and/or other conductive metals. FIG. 3 illustrates a connection between an exemplary superconducting lead 50a and adjacent normal metal conductors according to some embodiments of the present invention. The ends of lead 50a are covered by resistive metal sections 68a-b, while the middle of lead 50a is not covered by resistive metal in order to break the electrical connection between sections 68a-b when lead 50a is quenched.

In some embodiments, the operating temperature of leads 50a-b may be between 4 K and 90 K, for example between 10 K and 25 K. While higher temperatures are generally easier to attain, some materials may have suboptimal current handling properties at higher temperatures. For example, YBCO, though superconducting around 90 K, has limited current handling at that temperature. Moreover, a lower temperature may allow achieving lower noise values. A superconducting switch may be of particular use at relatively low temperatures that would lead to degradation in the performance of conventional silicon-diode-based switches.

In some embodiments, leads 50a-b are quenched by applying an initial pulse of super-critical current. The initial pulse overloads the superconductor(s) and renders the material(s) resistive. Subsequently, lower current values may be used to maintain leads 50a-b in a resistive state. In some embodiments, the initial pulse may have current values on the order of hundreds of mA to Amperes, while the subsequent applied current may have values on the order of mA to tens of mA. Some embodiments may employ applied voltage values between 0.1 V and 100 V, for example about 5 V, and resulting current values between 1 mA and 10 A.

FIG. 4 shows a structure of transmit/receive switch 40 according to some embodiments of the present invention. As shown, a cryogenically-cooled superconductor 50 forms transmit- and receive-path superconducting leads 50a-b. Transmit/receive switch 40 includes three RF-block, DC-pass filters 80a-c connected to DC power inputs DC In 1-3, respectively. In some embodiments, filters 80a-c have cutoff-frequencies on the order of MHz. The filter cutoff frequencies may be chosen to block the NMR frequencies of interest used by the system. DC power inputs DC In 1-3 are connected to DC power source 64 (FIG. 2). Each filter 80a-c is connected to a corresponding one of three switch nodes/terminals, respectively: a coil side node 82a, a transmit-side node 82b, and a receive-side node 82c.

To set transmit/receive switch 40 to the transmit state, the DC In 1-3 voltages are controlled to set the DC current flow through transmit-path lead 50a below the critical current of lead 50a (e.g. to substantially zero), and to set the DC current flow through receive-path lead 50b above the critical current of lead 50b. Transmit-path lead 50a thus remains superconducting, connecting transmit chain 52a to coil 24, while receive-path lead 50b becomes non-superconducting, effectively isolating amplifier 44 from transmit chain 52a. The isolation protects amplifier 44, and decreases transmit pulse losses to the receive coil. In some embodiments, receive-path lead 50b may be designed to provide isolation on the order of 60-80 dB.

To set transmit/receive switch 40b to the receive state, the DC In 1-3 voltages are controlled to set the DC current flow through transmit-path lead 50a above the critical current of lead 50a, and to set the DC current flow through receive-path lead 50b below the critical current of lead 50b. Receive-path lead 50b is then superconducting, connecting amplifier 44 to coil 24, while transmit-path lead 50a is non-superconducting, effectively isolating coil 24 and amplifier 44 from transmit chain 52a. With transmit-path lead 50a resistive and not impedance matched to the NMR coil(s), RF energy from the coil(s) travels preferentially along receive path lead 50b, and little or no RF energy travels through transmit-path lead 50a. The isolation may reduce the noise reaching amplifier 44, and thus reduce the noise temperature of the NMR detection circuit.

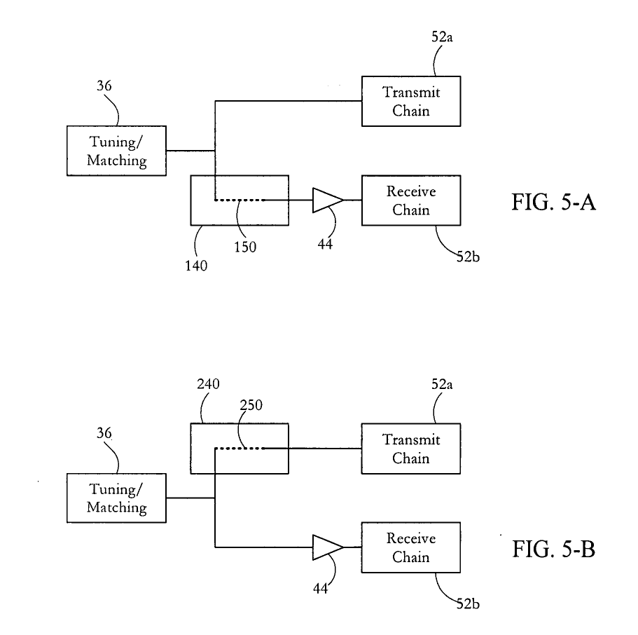

In some embodiments, a transmit/receive switch may include only one of the transmit-path and receive-path superconductor leads described above. FIG. 5-A shows an exemplary transmit/receive switch 140 according to some embodiments of the present invention. Switch 140 includes a receive-path superconductor lead 150 situated in an electrical path between tuning/matching circuit 36 and amplifier 44, and switchable between superconducting and normal states as described above. FIG. 5-B shows an exemplary transmit/receive switch 240 according to some embodiments of the present invention. Switch 240 includes a transmit-path superconductor lead 250 situated between tuning matching circuit 36 and transmit chain 52a, and switchable between superconducting and normal states as described above.

Exemplary embodiments described above allow achieving relatively low operating temperatures for NMR cold probe transmit/receive switches. Transmit/receive switches using silicon elements such as diodes may not perform adequately at such temperatures. Gallium arsenide diodes may perform at lower temperatures than silicon diodes, but gallium arsenide diodes may not be as robust as silicon diodes, and may limit the power levels of transmit pulses.

Lowering operating temperatures may lower the noise temperatures of the circuits, thus allowing improved signal-to-noise ratios in some embodiments. NMR signal-to-noise ratios generally may depend on the coil filling factor, which affects how much of the NMR signal comes from the sample relative to non-sample sources, the Q parameter, which is indicative of resistive losses in the system, and by the noise temperature, which provides a baseline level of noise. If the signal-to-noise ratio is proportional to (Q*filling factor/noise temperature)̂0.5, reducing the system noise temperature may allow improved signal-to-noise ratios for a given Q and filling factor.

The above embodiments may be altered in many ways without departing from the scope of the invention. For example, one or more superconducting switches as described above may be used in conjunction with silicon-diode-based switches. Accordingly, the scope of the invention should be determined by the following claims and their legal equivalents.

What is claimed is:

1. A nuclear magnetic resonance apparatus comprising:
a nuclear magnetic resonance radio-frequency coil; and
a transmit/receive switch electrically connecting the radio-frequency coil alternatively to a transmit circuit and to a receive circuit, the transmit/receive switch being switchable between a receive state and a transmit state, the transmit/receive switch including a receive-path superconductor situated in an electrical path between the receive circuit and the radio-frequency coil, wherein:
in the receive state, the receive-path superconductor is in a superconducting state, to connect the receive circuit to the radio-frequency coil;
in the transmit state, the receive-path superconductor is in a normal state, to isolate the receive circuit from the radio-frequency coil.

2. The apparatus of claim 1, further comprising a DC power source electrically connected to the receive-path superconductor and configured to quench the receive-path superconductor when the transmit/receive switch is in the transmit state.

3. The apparatus of claim 1, wherein the transmit/receive switch further comprises a transmit-path superconductor situated in an electrical path between the transmit circuit and the radio-frequency coil, wherein:
in the transmit state, the transmit-path superconductor is in the superconducting state, to connect the transmit circuit to the radio-frequency coil; and
in the receive state, the transmit-path superconductor is in the normal state, to isolate the transmit circuit from the radio-frequency coil.

4. The apparatus of claim 3, further comprising a DC power source electrically connected to the receive-path superconductor and the transmit-path superconductor and configured to quench the transmit-path superconductor when the transmit/receive switch is in the receive state; and quench the receive-path superconductor when the transmit/receive switch is in the transmit state.

5. The apparatus of claim 1, further comprising a receive-path amplifier electrically connecting the transmit/receive switch to the receive circuit, for amplifying nuclear magnetic resonance pulses received from the radio-frequency coil through the transmit/receive switch when the transmit/receive switch is in the receive state.

6. The apparatus of claim 1, further comprising a cryogenic fluid source fluidically connected to the transmit/receive circuit, for supplying a cryogenic fluid to the receive-path superconductor to maintain the receive-path superconductor below a critical temperature of the receive-path superconductor.

7. The apparatus of claim 6, wherein the cryogenic fluid source is fluidically connected to the radio-frequency coil, for supplying the cryogenic fluid to the radio-frequency coil.

8. The apparatus of claim 1, further comprising a tuning and matching circuit electrically connecting the radio-frequency coil and the transmit/receive switch.

9. A nuclear magnetic resonance method comprising:
applying a set of pulses to a nuclear magnetic resonance radio-frequency coil while quenching a receive-path superconductor situated in an electrical path between the radio-frequency coil and a receive-path amplifier; and
employing the receive-path amplifier to amplify a nuclear magnetic resonance response to the set of pulses while maintaining the receive-path superconductor in a superconducting state.

10. The method of claim 9, wherein quenching the receive-path superconductor comprises employing a DC current source connected to the receive-path superconductor to run super-critical current through the receive-path superconductor.

11. The method of claim 9, further comprising:
maintaining a transmit-path superconductor situated in an electrical path between the radio-frequency coil and a transmit circuit in the superconducting state while employing the transmit circuit to apply the set of pulses; and
quenching the transmit-path superconductor while employing the receive-path amplifier to amplify the nuclear magnetic resonance response.

12. The method of claim 10, wherein quenching the receive-path superconductor and quenching the transmit-path superconductor comprise employing a DC current source connected to the receive-path superconductor and the transmit-path superconductor to run super-critical current through the receive-path superconductor and the transmit-path superconductor.

13. The method of claim 9, further comprising employing a cryogenic fluid to cryogenically cool the receive-path superconductor.

14. The method of claim 13, further comprising employing the cryogenic fluid to cool the radio-frequency coil.

15. A nuclear magnetic resonance transmit/receive switch comprising a superconductor segment situated in a conductive path between a nuclear magnetic resonance radio-frequency coil and a receive circuit, the superconductor segment being switchable between a superconducting receive state and a quenched transmit state.

16. A nuclear magnetic resonance apparatus comprising:
a nuclear magnetic resonance radio-frequency coil;
a transmit circuit connected to the radio-frequency coil, for applying a set of measurement pulses to the radio-frequency coil;
a receive circuit connected to the radio-frequency coil, for detecting a response to the measurement pulses; and
a superconducting transmit/receive switch connected to the radio-frequency coil, transmit circuit, and receive circuit, for switchably connecting the radio-frequency coil alternatively to the transmit circuit and to the receive circuit, the transmit/receive switch comprising:
a first superconductor situated in an electric path between the transmit circuit and the radio-frequency coil; and
a second superconductor situated in an electric path between the receive circuit and the radio-frequency coil;
wherein the first superconductor and the second superconductor are switchable between superconducting and normal states to control an alternative connection of the transmit circuit and the receive circuit to the radio-frequency coil.
